(19) United States
(12) Patent Application Publication
(10) Pub. No.: US 2012/0222733 A1
(43) Pub. Date: Sep. 6, 2012

(54) ORGANIC PHOTOVOLTAIC CELL STRUCTURE

(76) Inventor: Charles V. Pownall-Ryan, Ajax (CA)

(21) Appl. No.: 13/392,982

(22) PCT Filed: Aug. 27, 2010
(86) PCT No.: PCT/CA10/01316

§ 371 Date: May 8, 2012

Related U.S. Application Data
(60) Provisional application No. 61/237,824, filed on Aug. 28, 2009.

(51) Int. Cl. H01L 31/0687

(52) U.S. Cl. 136/255

(57) ABSTRACT

The present invention provides a photovoltaic (PV) cell structure for enabling the conversion of incident light to potential electrical energy. The PV cell comprises at least one energy guiding means for converting incident light to potential electrical energy. The energy guiding means includes at least one electron donor and at least one electron acceptor adapted to be linked to a load therebetween. The electron donor is operable to release electrons based on absorption of photons and the electron acceptor may be operable to accelerate photons towards the electron donor and attract electrons released by the electron donor. The electron donor may include at least one photon receptor adapted to have a surface disposed at an angle normal to a range of incident photon angles.

### FIELD OF THE INVENTION

The present invention relates generally to photovoltaic or solar cells. The present invention more specifically relates to a multi-stage carbon-based photovoltaic cell having a high efficiency.

### BACKGROUND

Photovoltaic cells are used to generate electrical energy from sunlight. A photoelectric generator typically comprises a plurality of photovoltaic panels, each comprising a plurality of photovoltaic cells connected in parallel. The photovoltaic panels are arranged in a desired array, oriented to maximize the incidence of sunlight striking the panels, and connected in parallel to feed an output to a load or electrical storage device. The photoelectric generator so configured is capable of generating a flow of electrons which can be used to power a load, or stored as potential electrical energy in a battery or other storage device.

A conventional photovoltaic cell or “wafer” can generate a limited amount of power. For example, a standard one square meter photovoltaic panel can generate 150 to 200 millivolts (75 to 100 millivolts per cycle). As such, because of the broad surface area required to generate a significant voltage, photovoltaic cells are considered to be impractical for many applications.

Additionally, because a mechanism for moving such a large array of panels would be cumbersome and would itself consume considerable energy, typically a photovoltaic array is constrained to a fixed orientation, which results in the reduction of photon density on the surfaces of the photovoltaic panels as the sun moves away from a position normal to the photon-absorbing surfaces of the photovoltaic cells. In such an arrangement, maximum efficiency is only achieved during a portion of the day, because for much of the day the sun occupies positions in the sky which do not allow it to cast sufficient light on the stationary photovoltaic panels to saturate the photovoltaic cells.

It would accordingly be advantageous to provide a photovoltaic cell capable of converting a greater proportion of photonic energy into electricity, to thus maximize the energy available from a photovoltaic array.

It would further be advantageous to provide a system for increasing energy conversion efficiency of the photovoltaic cells when the sun occupies positions in the sky which are displaced from the optimal position normal to the photon-absorbing surfaces of the photovoltaic cells, to maximize the output of the photovoltaic array.

### SUMMARY OF THE INVENTION

The present invention provides a photovoltaic cell characterized by at least one energy guiding means, the energy guiding means including at least one electron donor and at least one electron acceptor, wherein the at least one electron donor is operable to release electrons based on absorption of photons and the at least one electron acceptor is operable to accelerate photons towards the at least one electron donor and attract electrons released by the at least one electron donor, wherein the at least one electron donor and the at least one electron acceptor are adapted to be linked to a load therebetween.

The present invention also provides a photovoltaic cell characterized by at least one energy guiding means, the energy guiding means including at least one electron donor and at least one electron acceptor, wherein the at least one electron donor includes at least one photon receptor adapted to have a surface disposed at an angle normal to a range of incident photon angles, the at least one photon receptor releasing electrons based on photons striking the surface, and the at least one electron acceptor is operable to attract electrons released by the at least one electron donor, wherein the at least one electron donor and the at least one electron acceptor are adapted to be linked to a load therebetween.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

### DESCRIPTION OF THE DRAWINGS

FIG. 1 illustrates the photovoltaic cell of the present invention, in one aspect thereof, wherein the photovoltaic cell comprises four stages, a conductive substrate, a conductive grid linking the substrate to the stages and a back contact for replenishing electrons in stages.

FIG. 2 illustrates electron diffusion between a donor material and an acceptor material in contact and under a forward bias.

FIG. 3 illustrates an energy guiding means having two layers of absorbing means disposed above and below a layer comprising a waveguide, in one aspect of the present invention.

FIG. 4 illustrates receptors constructed in a lattice across a plurality of nanotubes in accordance with the present invention, in one aspect thereof.

FIG. 5 illustrates the parabolic shape of a receptor, in one aspect of the present invention.

FIG. 6 illustrates photons striking the receptors of the photovoltaic cell.

FIG. 7 illustrates a partial view of the sinusoidal waveguide having three interleaved coils.

FIG. 8 illustrates a partial cross-sectional view of the sinusoidal waveguide having a large number of interleaved coils.

FIG. 9 illustrates the magnetic field influence of the sinusoidal waveguide on incident photons and corresponding released electrons.

FIG. 10 further illustrates the magnetic field influence of a waveguide element in a cross-sectional view thereof along the plane 10 shown in FIG. 7.

FIG. 11 illustrates a partial view of a plurality of carbon nanotubes comprising one receptor.

FIG. 12 illustrates a side view of the energy guiding means previously illustrates in FIG. 3.

FIG. 13 illustrates a top view of an O-ring circuit in accordance with the present invention.

FIG. 14 illustrates a top view of the waveguide having a sinusoidal shape and placed through the buses.

FIG. 15 illustrates a further top view of the waveguide having a sinusoidal shape and placed through the buses.

FIG. 16 illustrates a perspective view of a series of interleaved nanostrings comprising a nanostructure.

### DETAILED DESCRIPTION

The present invention, in one aspect thereof, provides a photovoltaic cell structure for enabling the conversion of incident light to potential electrical energy. The photovoltaic cell (hereinafter referred to as a “PV cell”) comprises at least one energy guiding means for converting incident light to potential electrical energy.

The present invention, in another aspect thereof, provides an energy guiding means for enabling the conversion to potential electrical energy of a particular wavelength range of light. The energy guiding means may comprise a plurality of layers including a plurality of layers comprising a plurality of absorbing means and a waveguide. The absorbing means may each be linked to a cathode and the waveguide may be linked to an anode. One absorbing means may be disposed above the waveguide and another absorbing means may be disposed below the waveguide.

The present invention, in another aspect thereof, provides an absorbing means that may comprise at least one set of receptors, wherein each set includes a plurality of receptors. A set of receptors may be provided within each cathode layer. Each receptor may be operable to absorb photons travelling with a velocity greater than a given threshold velocity, which is dependent upon the wavelength range to be absorbed. The absorption of the photons results in electron release by the receptors. The receptors may also be disposed in such a way as to enable maximum photon absorption even at times that individual receptors may be saturated. The receptors may be constructed from materials that enable the receptors to be optimally efficient for absorbing a particular wavelength range of light.

The present invention, in yet another aspect thereof, provides a waveguide used in association with the sets of receptors for both accelerating photons towards the receptors and attracting electrons released by the receptors for electrical conduction. One waveguide may be provided for each anode layer. Optimally, the waveguide is constructed from materials and in a structure that enable a maximum amount of charge to be carried by the waveguide.

The present invention, in yet another aspect thereof, provides a plurality of stages wherein each stage comprises an energy guiding means. In accordance with the PV cell of the present invention, one or more energy guiding means may be provided, one for each stage, within a particular PV cell for enabling the conversion of potential electrical energy from a wider wavelength range of light. In such an implementation, each stage may comprise different materials for absorbing different wavelength ranges of photons.

In a particular embodiment of the present invention, the PV cell is an organic PV cell comprised of a carbon based structure. For example, a carboloid and more specifically C-60 carboloid could be used as a base structure for forming particular aspects of the PV cell. In this embodiment, the PV cell may have a highly durable structure that also provides good electrical conversion efficiency over a wider range of temperatures than the PV cells of the prior art. For example, the PV cell may enable conversion when operating in a temperature range approximately from −40C to 100 C as opposed to typical PV cells that can only operate efficiently from approximately −10° C. to 40° C. An example of a PV cell in accordance with the present invention may comprise approximately 55% carbon, 40% to 45% silicon, and 5% to 10% conductive elements (geranium, indium).

### Photovoltaic Cell Structure

The present invention, in one aspect thereof, provides a PV cell having a structure optimal for enabling the conversion of incident light to electrical energy. The PV cell includes one or more stages, each stage including or being based on an energy guiding means that provides improved solar conversion efficiency. In one particular implementation of the PV cell, the PV cell is an organic PV cell.

The PV cell may comprise a plurality of stages encased within an encapsulate, each stage being adapted to absorb photons within a different wavelength range. The PV cell may be mounted on a conductive substrate representing one terminal of the PV cell. The conductive substrate may be, for example, a 5″×5″ ( 1/16″ to ⅛″ thickness) semi-flexible material formed from a plurality of 100 nm wafers composed of a carbon-based (carbide or carboloid) semiconductor material. In another aspect a mask may be created including 75 mm (squared) to 125 mm (squared) with a standard bus bar location, for example using the current new 8″ and 12″ wafer technology. The conductive substrate may be linked to a conductive grid further linked to a waveguide corresponding to each stage. Each stage may also be linked to a back contact further linked to a second portion of the substrate that is another terminal of the PV cell. The conductive grid and the back contact may be constructed from any conductive material, but as described more fully below is preferably a metal also having high thermal conductivity as well as electrical conductivity.

The two terminals of the substrate may be electrically insulated from one another by an insulative jacket. An array of PV cells may be created by mounting the cells on a B-type circuit board. A plurality of PV panels thus created may be arranged in any desired configuration, typically in planar alignment, and in a fixed disposition selected to optimize the capture of sunlight over the course of a day.

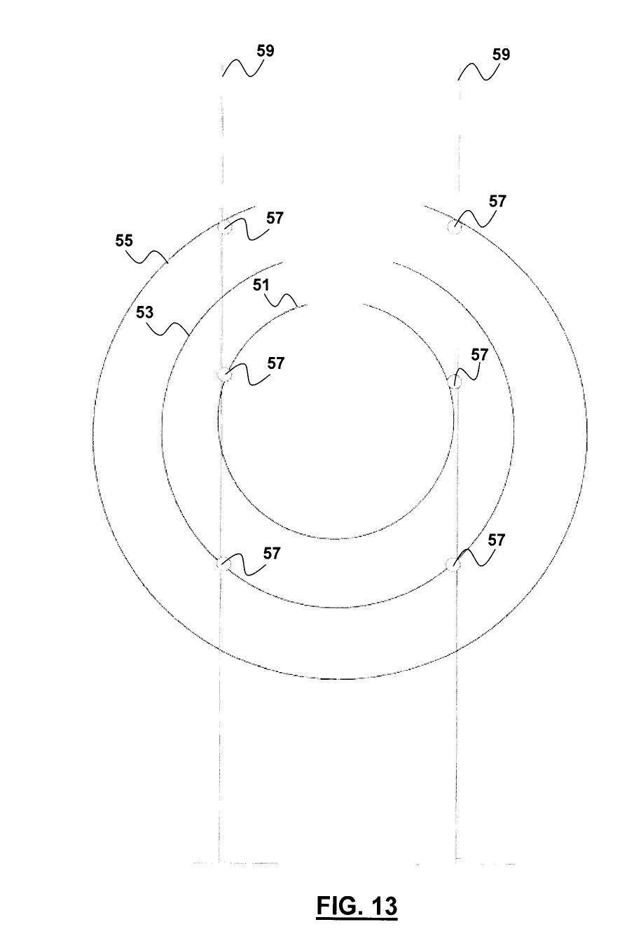

An alternate circuit design may be used having an O-ring configuration. The O-ring configuration may be preferable in larger wafers (for example, 100-125 mm) as it may be more efficient. FIG. 13 illustrates an O-ring circuit. The circuit may resemble an open O-ring as opposed to a closed circuit. The O-ring circuit may be a copper based compound. It may be approximately 200 nm in density. The O-ring circuit may be calibrated in size and shape based on the light spectrum to be absorbed and the degree of active energy to be released. For example, blue spectrum is much more energetic than yellow, which is much more energetic than red.

Each PV cell may comprise a tri junction cell with three embedded O-ring circuits (51, 53, 55). The O-ring circuits may be centrally located within the cell and the size of each O-ring may be dependent upon spectral layer. The O-rings may be adjacent, or close, to the vertical pin outs (57) without touching the pin outs in order to allow current transfer without hot spots. The vertical pin outs may be directly connected to the top layer buses (59) which carry positive and negative current. Vertical pin outs (57) may also be connected to the base heat sink in order to dissipate any excess heat.

The stages may be formed one on top of the other, where “top” indicates a light-incident stage and “bottom” indicates the stage adjacent the substrate. The stages may be disposed such that photons of higher energy (and higher frequency) are absorbed nearer the top stage and photons of lower energy (and lower frequency) are absorbed near the bottom stage.

The stages may be formed from a plurality of carbide-based layers for efficient photon absorption and subsequent electron excitation. Optimally, a high proportion of the layers are composed of the carbide. The carbide may be a fullerene. The fullerene may be a C₆₀ carboloid. The carbide may also be a Si C carboloid hybrid.

The base elements in each anode layer may include carbon (primarily in the C₆₀ form) and trace amounts of nickel, zinc and copper but possibly also indium, cadmium, geranium. In addition, each cathode layer may be provided with a substantial amount of a photon-absorbing element chosen to most effectively absorb photons within a selected range of the sunlight spectrum, as more fully described below.

The PV cell components may be nanowires or nanostrings produced using for example an electro-spinning process. Current electro spinning enables nanowires of density 100-200 nanometres to be produced efficiently and consistently, however it should be understood that higher densities will be possible in accordance with nanospinning evolution. The nanowires may, for example, have a density of density 100 nanometers. The O-ring circuit and vertical pin outs may, for example, have a density of 200-300 nanometres.

The waveguide may, for example, have a density of 100 nanometres. For example, three to seven nanowires may be coiled in a pre-defined pattern, creating the waveguide pattern described more fully below. The coiled structure may have a density of approximately 300 nanometres. The coiling may be produced as the nanowires come out of the electro spinner. Rotating air pressure may be used to spin the wires into a coiled shape. This structure is then fitted to an etched surface in the shape of a natural sinusoidal wave form.

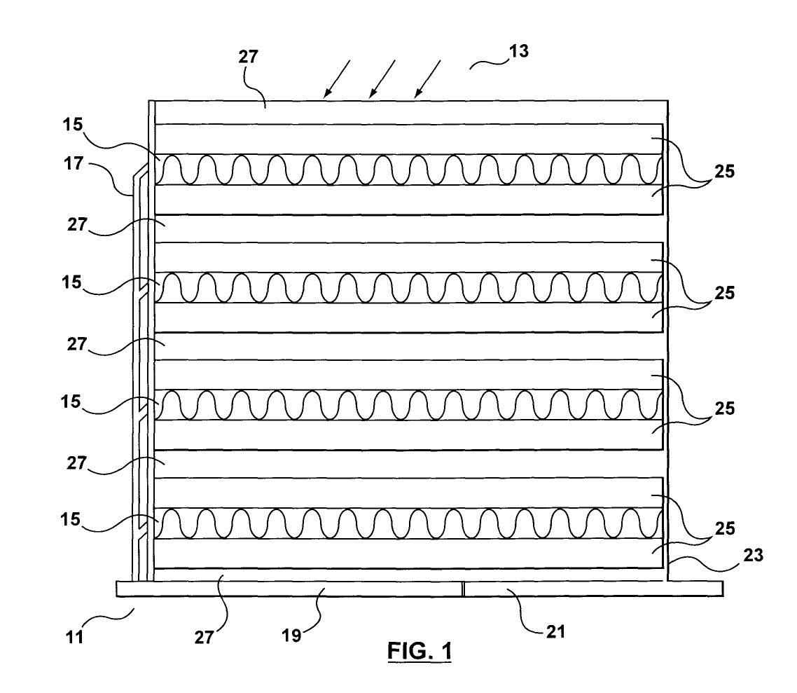

FIG. 1 illustrates the photovoltaic cell of the present invention, in one aspect thereof. More particularly, FIG. 1 shows a four stage PV cell 11 having four energy guiding means, a conductive substrate 19, 21, a conductive grid 17 linking the substrate 19 to the energy guiding means and a back contact 23 for replenishing electrons in the energy guiding means.

### Energy Guiding Means

The present invention, in another aspect thereof, provides an energy guiding means for enabling the conversion of a particular wavelength range of light to potential electrical energy. The energy guiding means may optimize the absorption efficiency of incident photons, which corresponds to an optimization in the number of released electrons. This may be calibrated through calculation of the wavicle harmonics of the standing wave based on the particle resonance frequency, as is known in the art, and, therefore, generated electrical energy.

In one aspect of the energy guiding means, the energy guiding means is disposed such that (1) there is optimal absorption of the photons and an even distribution of excitation of the base substrate along the waveguide, and (2) electrons are directed efficiently and at a higher density toward an output to a load, such as an electrical storage device or a DC/AC inverter device, for example. Thus the energy guiding means may provide optimal overall energy capture, especially in combination with improved heat dissipation as described more fully below.

The energy guiding means may comprise a plurality of layers including a plurality of cathodes 25 and an anode 15. One cathode 25 may be disposed above the anode 15 and another cathode 25 may be disposed below the anode 15. Each cathode 25 may also be referred to as an electron donor, or simply donor. The anode 15 may also be referred to as an electron acceptor, or simply acceptor. The back contact 23 may also be linked to a back contact layer 27 disposed adjacent to each cathode layer 25 as shown in FIG. 1.

Furthermore, the donor may be an n-type material and the acceptor may be a p-type material in the context of inorganic semiconductors. Other implementations, however, are possible including for inorganic semiconductors where the terms donor and acceptor may not strictly refer to n-type and p-type materials, but are understood to be analogous thereto. The terms donor and acceptor are used herein for explaining the structure of the energy guiding means as it relates to both organic and inorganic semiconductors.

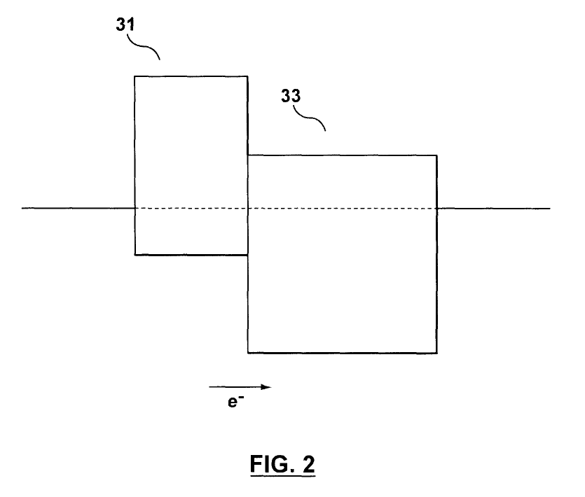

The donor and acceptor materials, when placed in contact along a plane, enable charge transfer through processes such as electron depletion and excitation diffusion, depending on the particular materials involved (the term “excitation diffusion” is used herein to denote these processes generally). During excitation diffusion, electron charges diffuse from the donor to the acceptor. FIG. 2 illustrates electron diffusion between a donor material 31 and an acceptor material 33 in contact and under a forward bias.

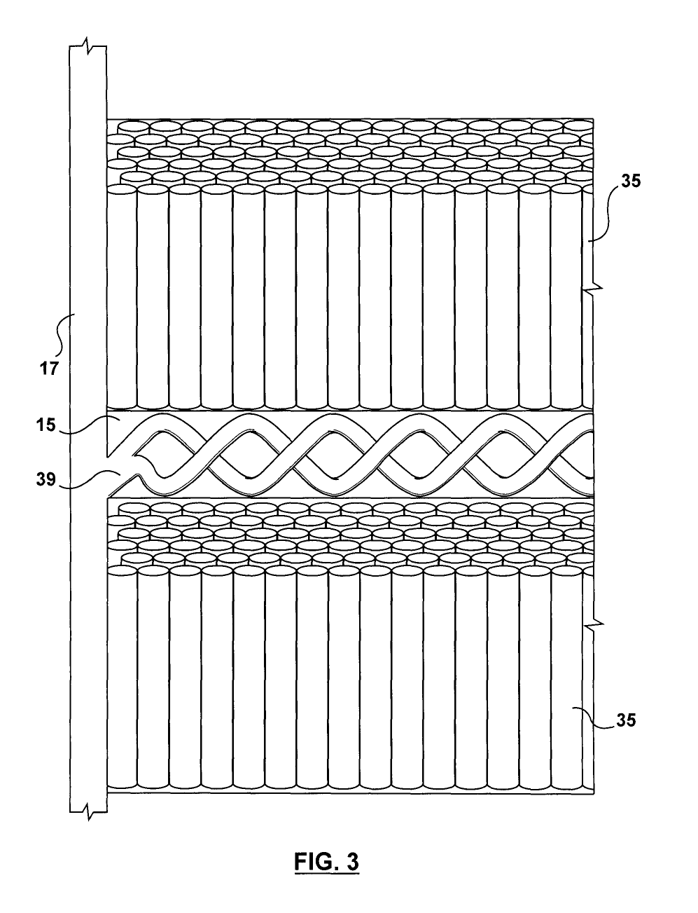

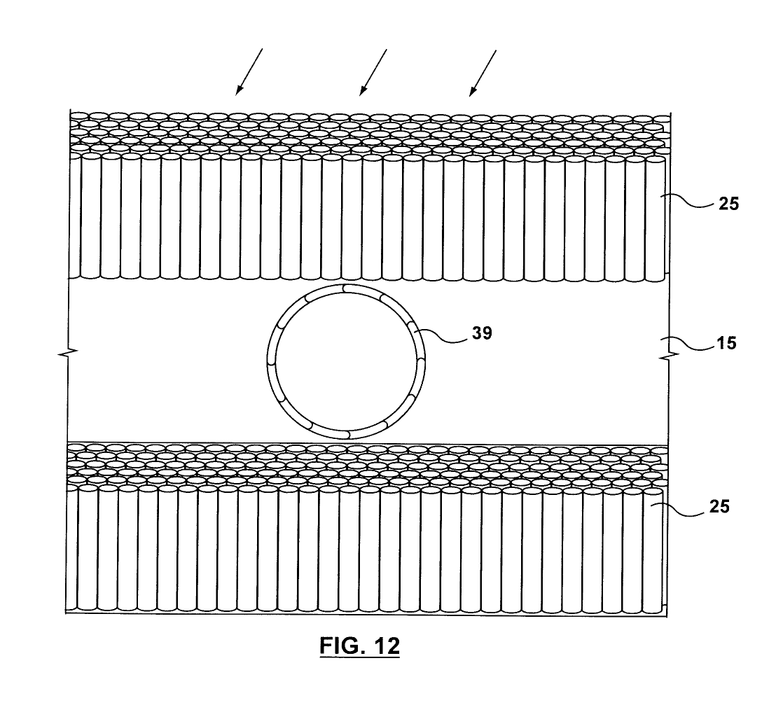

Furthermore, the energy guiding means comprises at least one absorbing means and a waveguide. Each absorbing means may be disposed within the cathode layers and the waveguide may be disposed within the anode layer. FIG. 3 illustrates two layers of absorbing means 35 disposed above and below a layer comprising the waveguide 39, in one aspect of the present invention. FIG. 12 illustrates a side view of the three layers of the energy guiding means wherein the waveguide 39 does not span the entire width of the anode 15 layer. This configuration enables incident photons to pass through the anode 15 toward the lower of the two cathode 25 layers.

The two layers of absorbing means 35 may be constructed for absorbing a particular wavelength range of incident light. Optionally, the two layers of absorbing means 35 may be constructed to absorb different wavelength ranges of incident light. Optionally, just one layer of absorbing means 35 may be provided in the energy guiding means, in which case the absorbing means 35 is optimally disposed above the waveguide 39 but could be disposed below the waveguide 39.

The absorbing means, in an implementation of the present invention discussed in greatest detail herein, is best understood as a nanostructure having the characteristics more fully described below. The absorbing means is operable to absorb photons travelling with a velocity greater than a given threshold velocity and release electrons when such photons are absorbed.

The waveguide, which is also more fully described below, may have a slight positive influence, which enables the generation of a magnetic field for accelerating photons towards the absorbing means such that the photons have a greater likelihood of surpassing the required threshold and for attracting and receiving the corresponding released electrons.

### Absorbing Means

The present invention, in another aspect thereof, provides an absorbing means that may comprise at least one set of receptors, wherein each set includes a plurality of receptors. In one aspect of the present invention, the receptors may be constructed in a lattice within a single nanostructure or across a plurality of nanostructures. The nanostructures may be nanotubes (such as carbon nanotubes), quantum dots or nanostrings or nanowires. The nanostructures may also consists of pressed nano-crystals provided in accordance with known methods, for example, using vapour deposition to apply the nano-crystals to a wafer, and then application of positive pressure to create the pressed nano-structures. It should be understood that the references to nanotubes in this disclosure should be understood to refer also to alternate nanostructure that have the characteristics described herein such as the mentioned pressed nano-crystals. It should be understood that the cells based on pressed nano-structures are easier to manufacture. In order to best explain the absorbing means, the following description includes the use of nanostructures; however the use of other structures follows similar techniques and principles.

The nanostructures may also comprise other materials enabling optimal absorption of a particular wavelength range of light. The material composition of the nanostructures may be substantially opaque to light having a wavelength within the desired spectral component range and substantially transparent to other wavelengths of light. In a multi-stage PV cell, as described more fully below, each stage may comprise different material compositions for collectively absorbing a wide wavelength range of light. One example of the particular material compositions for the stages are described more fully below.

The nanostructure provides a structure for optimizing photon absorption, whether when the PV cell is exposed to direct sunlight, or when the sun occupies positions in the sky which do not allow it to cast sufficient light on stationary PV panels to saturate the PV cells (i.e. in low ambient light, where the sun generally casts light on stationary PV panels in oblique angles).

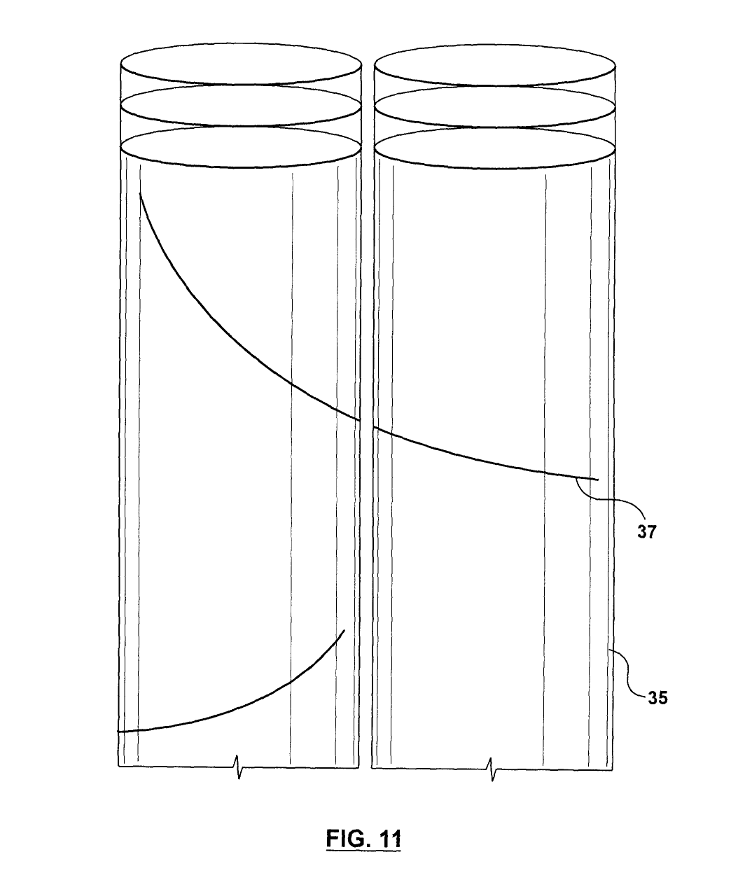

FIG. 11 illustrates a partial view of a plurality of carbon nanotubes comprising a receptor. The nanostructures comprise a carbon bonded structure as is known. Receptors may be formed in crystalline arrangements dispersed in or across the nanostructures. There may not be any bond formed between the crystalline arrangements and the nanostructures, as such a bond may result in a short circuit or hot-spot created within the absorbing means. Instead, the receptors 37 may be aligned relative to the nanotubes 35 to achieve the concave differently oriented arrangements described below. However it should be understood that levels of nanotubes 35 may be bonded together, for example using optionally hydrazine as a bonding agent at the carbon level.

Alternatively, the receptors may be dispersed in or across a Si C bonded nano-crystal lattice that includes a carbon nano-substrate layering pressed into the lattice using air pressure in vacuum. The additional carbon nano-substrate pressed into the Si C lattice will supplement the base structures electron replenishment process.

As depicted, a receptor 37 is formed across the nanotubes 35 by the doping element (also referred to herein as the base element) which forms ionic bonds within each carbon structure and surface layer valence bonds to receptors 37 of adjacent carbon structures. The number and disposition of the bonds may be dependent upon the base element chosen for the particular wavelength range of light. Alternatively, a pulse laser may be used to both form the concave structures that are part of the nanostructure, and further to bond the layers used in creating the nanostructures. The bonding process using a high frequency pulse laser may create a fusion bond or weld layer to layer. In addition the laser may be calibrated to pulse at different angles to provide the concave lattice structure that can optimize photon absorption at differing (oblique) angles of sunlight. Thus, the pulse laser process may provide optimal configurations of the concave lattice structure while at the same time providing a weld or fusion bonding of the successive layers together.

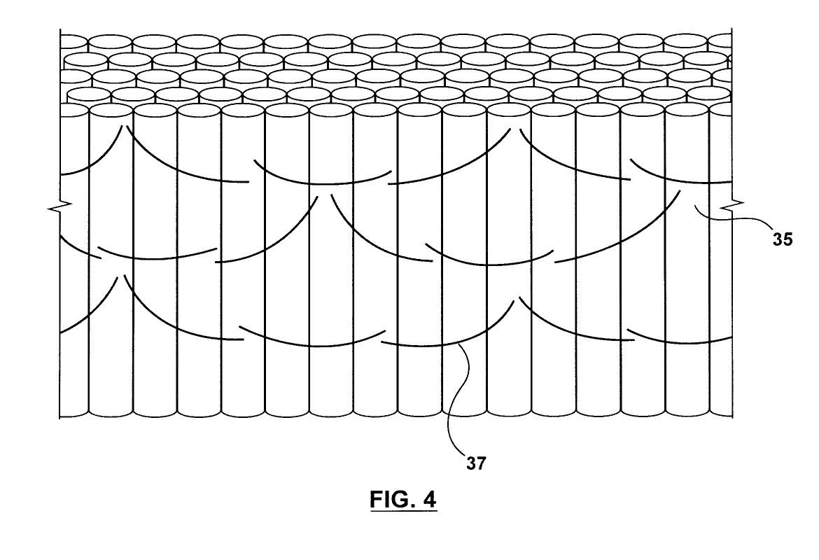

FIG. 4a illustrates a plurality of receptors 37 constructed in a lattice across a plurality of nanotubes 35 in accordance with the present invention, in one aspect thereof. The nanotubes 35 may be disposed vertically as shown, horizontally, diagonally or in a variety of dispositions. The term vertically should be understood to mean at an angle perpendicular to the light-incident surface of the encapsulate.

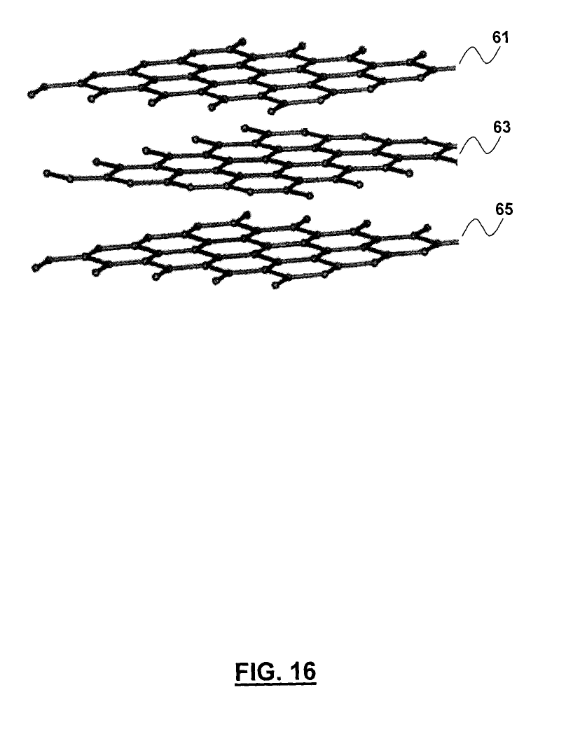

Alternatively, the nanostructure could consist of a series of interleaved nanostrings, as shown in FIG. 16, made using an electro-spinning process. The electro-spinning technique can be adapted so that the interleaved nanostructure includes the concave shapes. The nanowire structure may resemble a stand woven cloth fabric. Each layer (61, 63, 65) may be interleaved into a similar pattern and successive layers may be offset from each other to provide a woven effect.

It should be noted that in FIG. 4 adjacent rows of nanotubes 35 are not shown to be in contact, however the adjacent rows may be in contact.

Furthermore, the nanotubes can be stacked one on top of and in close proximity to the other (but optimally not directly in contact) within each absorbing means.

It has been observed that a vertical disposition (or more specifically, at the angle of incident light) may provide the most optimal absorptive results. This can be explained by the vertical structures guiding incident photons toward the receptors embedded therein, rather than having incident photons potentially “bounce” off of the nanostructures or lose velocity based on travel through the nanostructures if the nanostructures are disposed at angles normal to that of the incident light.

Additionally, the nanotubes may be disposed in rows and columns (not shown) or could be staggered from row to row (as shown in FIG. 4). It has been found that staggering the nanotubes increases the receptor density and provides more optimal results.

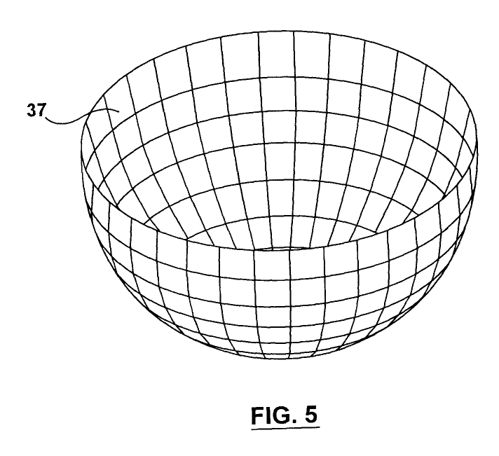

The receptors may be shaped to optimize photon reception at varying angles of incidence of light. In one particular implementation as shown in FIG. 4, each receptor 37 may have a concave shape in profile view or, more specifically, a three dimensionally parabolic shape (hereinafter referred to simply as “parabolic” but understood to mean three dimensionally parabolic). FIG. 5 illustrates the parabolic shape of a receptor 37, in one aspect of the present invention.

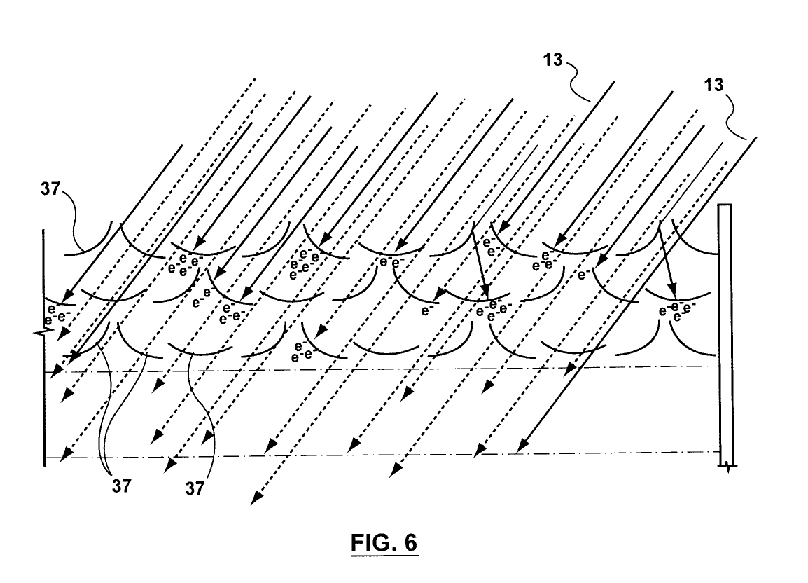

To compensate for times during the day when the sun occupies positions in the sky which are displaced from the optimal position normal to the exposed surface of the PV cells, and thus to maximize the incidence of photons striking the stages of the cell and optimize collection of photonic energy, the concave receptors 37 may have a curved structure providing a surface normal to the direction of sunlight for a large range of incident angles. As illustrated in FIG. 6, angles of incidence of the sunlight closer to the normal may provide greater photon densities striking the surface, greater photon absorption, and greater numbers of electrons released.

It should be understood that in order to optimize performance of the absorbing means based on sunlight conditions that vary depending on geography, the angles of incidence for each receptor 37 may be established to address such variations based on known mathematical calculations (e.g. using the point of 0 as a base for establishing at a given latitude an optimal angle of incidence for each receptor as described above).

The receptors may be formed optionally by a gasification/condensation (also referred to as plasma precipitation) technique, using a magnetic flux press to form the parabolic configurations. The gasification/condensation process can be carried out based on the results of the mathematical calculations for establishing angles of incidence for each receptor referenced above. A magnetic field influence is used to actually form the receptors using the base elements or compounds as more fully described below. The base elements may form bonds to the carbon nanostructure.

The receptor surfaces may be batch-formed at the desired angles by embedding absorptive base elements or compounds such as iridium (further elements and compounds are described more fully below) embedded in a transparent substrate such as a C₆₀ carboloid, silicon, germanium or gallium structure aligned for transparency. In this fashion multiple levels of receptors disposed to different angles can be overlaid in a multi-level receptor array if desired, to direct incident light over as much of the surface of the absorbing means as possible. Within each level of receptors, individual receptors 37 may be disposed at varying angles for optimizing the absorption of incident light, as can be seen in FIG. 6.

The absorbing means may be composed of a plurality of levels, as illustrated in FIG. 4 and FIG. 6, disposed in a staggered fashion such that, within a particular level and across the levels, the receptors are misaligned vertically within the absorbing means, significantly increasing the probability that as photons progress through the levels they are eventually captured by one of the levels of receptors and directed toward the photon-absorbing matrix in that sequence of layers. The multi-level structure enables photons to be absorbed by lower-level receptors even when higher-level receptors are fully saturated, when higher-level receptors are not struck by particular photons, when higher-level receptors are struck at extremely oblique angles to the receptors such that the normal vector of the photon travel to the receptor does not exceed the velocity threshold, and when photons ricochet off a given receptor at an oblique angle.

Optimally, the highest level of receptors is near the upper plane of the absorbing means and the lowest level of receptors is near the lower plane of the absorbing means. It has also been found that for high frequency photons more levels are typically required than for low frequency photons. For example, an ultraviolet absorbing means may be provided optimally with greater than twenty levels of receptors whereas an infrared absorbing means may be provided optimally with approximately six levels of receptors.

In a further embodiment (not shown) the receptors may alternatively be in groups disposed at varying angles such that, over the array of receptor levels, groups of receptors change angles in increments in a plane through a 180 degree east-west horizon, in order to capture solar energy in a relatively high average concentration for as much of the day as possible as the sun moves across the sky. An angle of 3 degrees may be optimal. The receptors and/or levels of receptors may also be differentially-spaced if desired.

The concave receptors may optionally be optimized relative to the positional influence of the waveguide. If desired the receptors in the cathodes both above and beneath the waveguide may be disposed such that focal point of each receptor is disposed based on the waveguide phase angle directly above or below the receptor, as illustrated in FIG. 6. As will be described more fully below, this disposition may enable released electrons to be more optimally attracted to and captured by the waveguide.

Optionally, the disposition of the receptors in each level may be incremented, for example in 1 degree increments, through a north-south lateral plane, through about 30 degrees (depending upon the latitude at which the PV cell is disposed). In non-equatorial positions this may further optimize the amount of the parabolic surface actually receiving photons, which optimizes photonic energy absorption taking into account seasonal north-south positional changes of the sun.

Each receptor may be generally parabolic, for example with a radius of up to 100 nm. From one absorbing means to the next the angle of the receptors and their radii can be varied as the depth within the PV cell increases, increasing the tendency of successively lower layers to capture lower frequency photons. Furthermore, the parabolic shape need not have the same dimensions in one axis as in its other two axes, for example where the particular location of the installation of a photovoltaic panel is known and the parabolic shapes can be adjusted to optimize absorption based on the azimuth of the sun and other factors.

The receptor matrices may follow the same density patterning as the stages. The receptor layers in the top stage absorbing means may be more densely populated with receptors, to capture and concentrate shorter wavelength photonic energies; and the receptor layers in the lower stages may be less densely populated with receptors to capture and concentrate progressively longer wavelength photons. In other words, the receptor density within a row, and the row density, may be greater near the top of the cell to more effectively capture high frequency (short wavelength) photons, and the receptor density within a row, and the row density, may decrease as the depth into the cell increases, more effectively capturing increasingly lower frequency (longer wavelength) photons. The angling of 3 degree increments through a 180 degree east-west horizon plane and 1 degree increments through a 30 degree north-south seasonal plane may be fully replicated for each stage, but within each stage the rows of receptors may be staggered to maximize photonic capture and concentration.

Again the changing direction of the receptors may be staggered as between levels in any particular absorbing means, and/or from one sequence of layers to the next, to maximize the probability of capturing photons within the intended wavelength range for that stage.

Alternatively, a nano-scale mirror and lens array layer may be provided for concentrating photons to the receptors. The mirror and lens array may also have a parabolic structure similar in form to the receptors described above. The mirror and lens array may reflect and refract incident light to a concentrated point or points of the absorbing means. The mirror and lens array layer may be composed of a dense carbon or carboloid having a high reflectivity and preferably good thermal conductivity, serving as a secondary heat sink. The mirror and lens array layer may also be formed by conventional gasification/condensation techniques using a magnetic flux press to form the nano-mirror configurations. The mirror and lens surfaces may be batch-formed at the desired angles by embedding reflective surfaces, composed for example of a C₆₀ carboloid aligned for reflectivity, embedded in a transparent substrate, composed for example of a C₆₀ carboloid aligned for transparency. In this fashion multiple layers of mirrors and lenses having different angles of reflectance and refraction can be overlaid in the mirror and lens array layer if desired, to direct incident light over the as much of the surface of the absorbing means as possible.

In operation, photons 13 having a wavelength within the desired spectral component range (shown as arrows with solid lines in FIGS. 1 and 6) may strike the receptors. Most of these photons 13 may be absorbed by one of the levels of receptors, some after reflecting off of receptors in the higher levels and being absorbed by receptors in the lower levels. Occasionally a photon 13 having a wavelength within the desired spectral component range may pass through all levels (for example, the photon on the far right in FIG. 6), in which case the photon may be absorbed by the other absorbing means of the energy guiding means, another stage as more fully described below or may be occasionally dissipated as heat. When a photon is absorbed by a receptor, the receptor releases an electron that can be attracted to and captured by the waveguide as described below.

### Waveguide

The present invention, in yet another aspect thereof, provides a waveguide used in association with the sets of receptors for both accelerating photons towards the receptors and attracting electrons released by the receptors for electrical conduction. The waveguide may be formed to provide phase insensitivity or indifference such that it is operable to attract released electrons regardless of each electron's phase as it comes in close proximity to the waveguide.

One waveguide may be provided for each anode layer. Optimally, the waveguide is constructed from materials and in a structure that enable a maximum amount of charge to be carried by the sinusoidal waveguide. The waveguide, in one aspect of the present invention, is comprised of a semi-conductive carbon structure. More particularly, the waveguide is a carboloid which may be a C60 carboloid. The waveguide may also be a Si C hybrid carbide. The waveguide may also comprise one or more trace elements including zinc, copper and nickel for increasing the conductivity of the waveguide.

The waveguide may be disposed in close proximity to, but not in contact with, the conductive grid, which itself has a positive charge. This disposition enables the waveguide to absorb the magnetic energy from the positive polymer, which causes a positive influence on the waveguide, further enabling the waveguide to develop a magnetic field that influences photon and electron travel within the absorbing means. The magnetic field's influence optimally fully encompasses the cathode layers associated with the waveguide's anode layer and does not extend to energy guiding means of other stages of the PV cell, which each comprise their own waveguide.

Typically, when electrons are released from the absorbing means due to photon absorption, the electrons are released in various directions as free electrons. However, the positive influence of the waveguide and close proximity to the absorbing means enables released electrons to be attracted to the waveguide which allows for a flow of a higher density of electrons during the photon excitation in conversion.

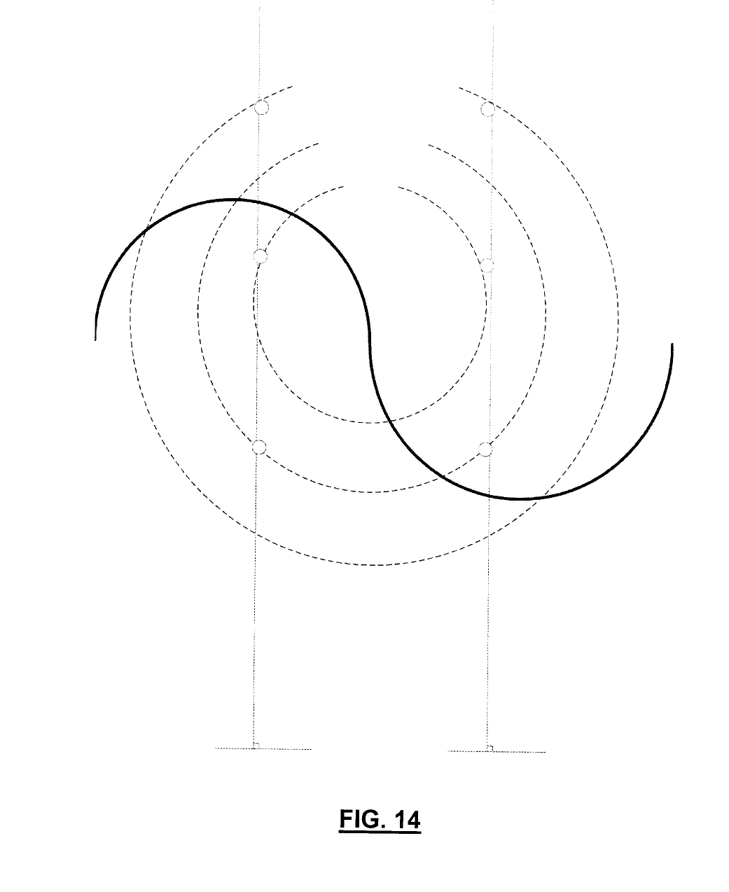

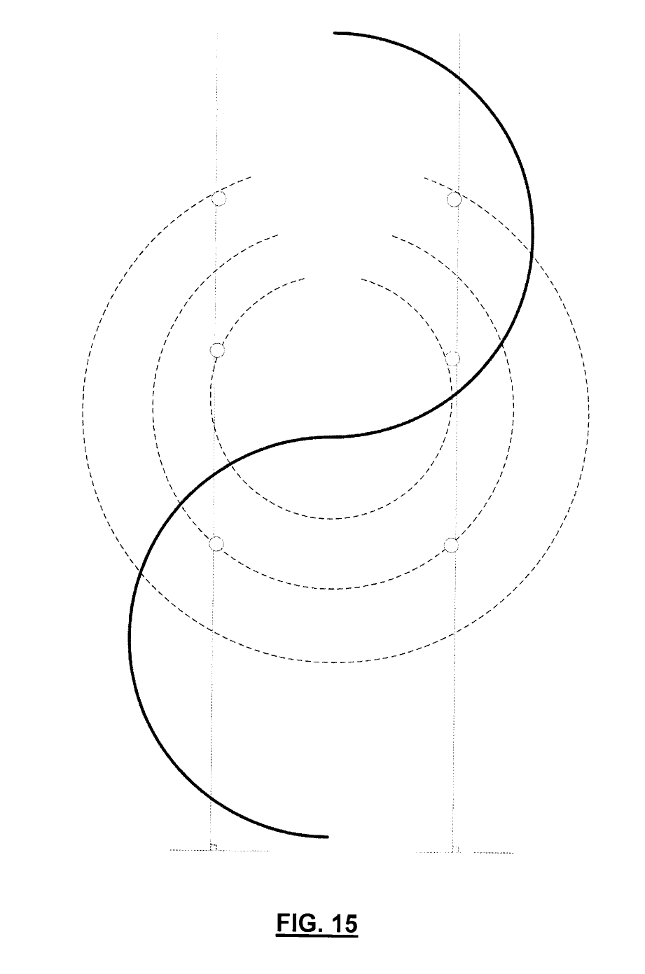

In one aspect of the present invention, the waveguide is comprised of a plurality of three dimensional sinusoidal waveshaped elements, which more specifically is a plurality of helical elements or a plurality of interleaved coils (hereinafter referred to as a “sinusoidal waveguide”). The waveguide through the buses may have a sinusoidal shape that is best illustrated in FIGS. 14 and 15. The baseline may begin in the bottom left (south west) corner of the cell. The first arc of the sinusoidal pattern may be at the top of the left bus. The pattern may continue and the second are may be at the bottom of the right bus. It may continue to the top right or north east corner. This results in the “0” point or balanced energy point of the waveguide in the exact centre of the cell wafer.

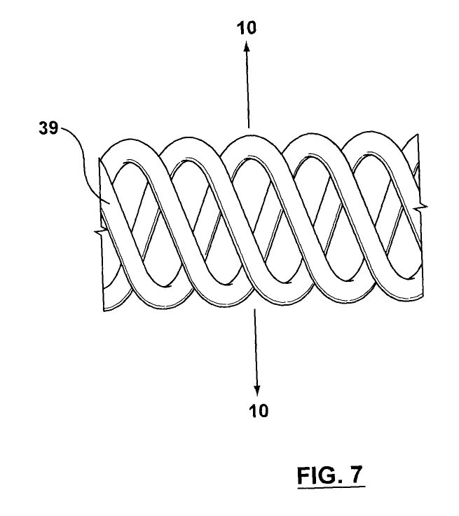

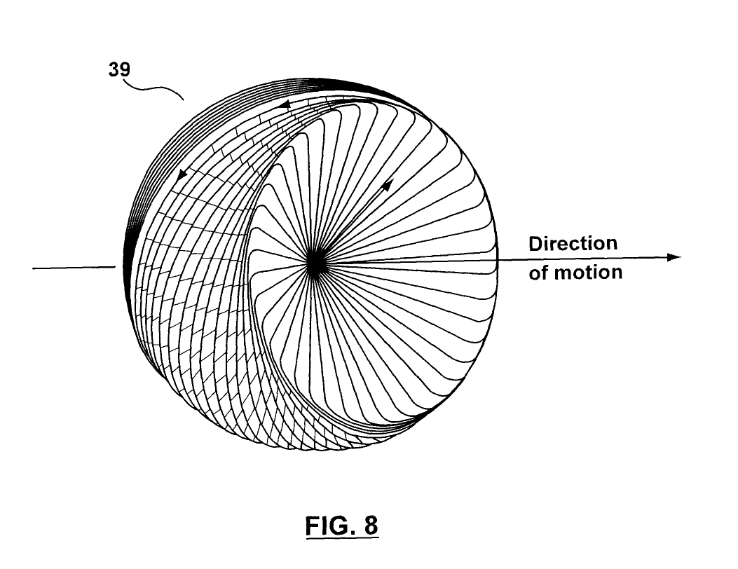

The sinusoidal waveguide is illustrated in FIG. 3 having two interleaved coils, in FIG. 7 as a partial view having three interleaved coils and FIG. 8 in partial cross-sectional view having a large number of interleaved coils. Optimally, a large number of densely packed interleaved coils are provided, for reasons described below. However, the interleaved coils should not be in contact.

This embodiment of the waveguide enables smooth photon and electron guidance. The magnetic field influence disposed about the sinusoidal waveguide accelerates photons to the receptors of the absorbing means, enabling a greater number of photons to surpass the threshold velocity required for photon absorption, resulting in a high proportion of released electrons. The magnetic field influence also enables an attraction to the waveguide of released electrons. Furthermore, due to the sinusoidal waveshape of the waveguide, there is a high likelihood that there will be a magnetic field proximate the attracted electron that has a phase optimal for capturing the electron and guiding it along the waveguide to the conductive grid. Higher likelihoods of the phase compatibility may be obtained by having more interleaved and more densely packed sinusoidal elements in the waveguide as is shown in FIG. 8 as opposed to FIG. 3 or 7. Thus the sinusoidal waveguide may be phase immune or phase insensitive.

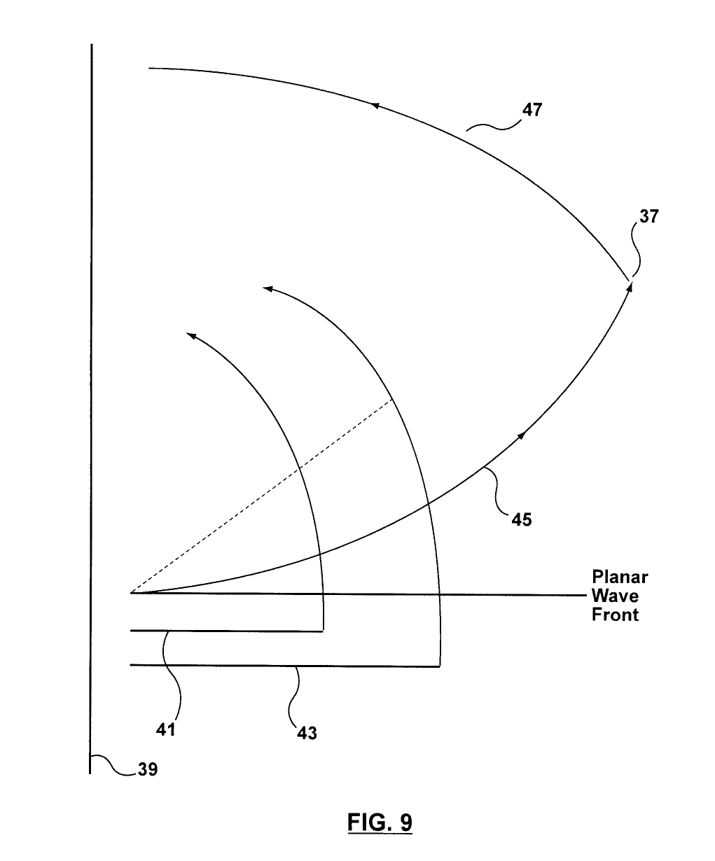

FIG. 9 illustrates the magnetic field influence of the sinusoidal waveguide on incident photons and corresponding released electrons. As the incident photon, travelling along a planar wave front 41, comes within the waveguide's 39 influence it experiences a tangential acceleration 43 caused by the magnetic field influence in a direction about the waveguide. This influence accelerates the photon towards the receptors 37, resulting in a high likelihood of electron release.

The released electron is also directed 47 by the influence of the waveguide 39 in a direction towards the waveguide 39. The electron has a particular phase when it comes in close proximity to the waveguide 39 and the sinusoidal waveshape of the waveguide 39 enables its magnetic phase along any given point to be within a tolerance of the phase of the electron, resulting in a high likelihood of capturing the electron. The number of such in-phase angles may be proportional to the number and density of interleaved elements. The captured electron is then directed along the waveguide 39 to the conductive grid seen in FIG. 3.

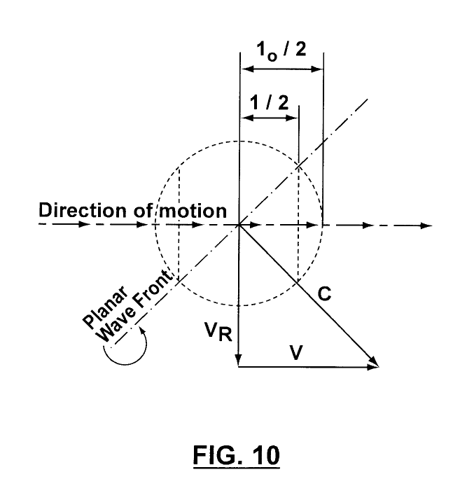

FIG. 10 further illustrates the magnetic field influence of a waveguide element in a cross-sectional view thereof along the plane 10-10 shown in FIG. 7. As can be seen in FIG. 10 the wavicle (i.e. the photon or the electron) has a rotation, following a radial circle, defining its phase that may or may not be within the tolerance of the particular phase of the point of the waveguide element depicted. However, points along the plane 10-10 of other waveguide elements interleaved with the element shown may be in-phase with the wavicle's rotation. This optimization of the probability that at least one element of the waveguide is in-phase with the wavicle results in a length contraction that enables optimal acceleration of the photon and optimal absorption of the electron.

In another aspect of the present invention, the waveguide is a linear waveguide. A linear waveguide may not provide all of the advantages of the sinusoidal waveguide, such as phase insensitivity. However, a linear waveguide comprised of the materials described above may be provided for capturing electrons and directing captured electrons to the conductive grid.

### Forming Process

The semiconductor layers in each stage may be approximately 100 nm. Preferably, the semiconductor layers are less than 100 nm, and more preferably about 30 nm in thickness. The layers may be formed using a gas condensation process, which is also known as a gasification/condensation process or a plasma precipitation process, in which magnetic flux is first used to form the nanostructures making up the layers, the carbon and base elements are then heated and cooled to condense in the desired substrate format, and the base mole layer is then pressed to a high density solid design. Optimum efficiency may be achieved by providing semiconductor layers ranging from 30-50 nm; however layers up to and even greater than 100 nm will still be effective.

Different gasification/condensation processes may also be used.

The back contact may be formed in a sinusoidal shape in a housing between the anode and cathode layers, and then the layers may be pressed by a magnetic field resonating at the desired frequency to create the sinusoidal pattern, which may for example be determined as follows: when electron excitation occurs from the passing of the photonic energy, the electron may develop translational velocity.

FIG. 10 illustrates the relative magnitude and direction of the changing electron/electromagnetic field due to the translational velocity. As the translational velocity occurs, this is defined as tangential velocity V_{R}, with R₀, being the center of the electron (at rest) and V being the translational motion (direction) of the electron. The natural sinusoidal wave pattern becomes helical in nature as velocity increases in direction of the positive polymer energized by the passing photon. Therefore:

$$T = \frac{2 π R}{{V}_{R}} = \frac{2 π R}{{( {C}^{2} - {V}^{2} )}^{\frac{1}{2}}} ,$$

and therefore:

$$T = \frac{{T}_{0}}{{( 1 - \frac{{V}^{2}}{{C}^{2}} )}^{\frac{1}{2}}} .$$

Thus, it can be seen that the wavicle energy potential will increase with the increase in tangential velocity toward the waveguide in direct relation to the energy absorbed from the passing photon. This is the expression of the time dilation that occurs as the electron excitation occurs from the passing photons and absorption of the photonic energy. These equations can be used to determine the optimum sinusoidal shape of the waveguide and back contact in order to provide the lowest impedance to the path of the electrons through these structures.

The wave front may develop a helical sinusoidal wave pattern about the electron as in develops tangential velocity. This may vary dependent upon the energy of the photon, and this is dependent upon the spectrum being attracted, causing electron excitation. Higher light frequencies create greater excitation, and vice versa.

### Stages

The present invention, in yet another aspect thereof, provides a plurality of stages wherein each stage comprises an energy guiding means as more fully described above. In accordance with the PV cell of the present invention, one or more energy guiding means may be provided, one for each stage, within a particular PV cell for enabling the conversion of potential electrical energy from a wider wavelength range of light. In such an implementation, each stage may comprise different materials for absorbing different wavelength ranges of photons.

The PV cell structure of the present invention may be implemented as a multi junction PV cell wherein each junction is a donor acceptor junction. Each stage may be formed as previously described, including two cathode layers each comprising an absorbing means disposed above and below an anode layer comprising a waveguide. Each waveguide may be disposed in proximity to a conductive grid for transferring electrons from the waveguides to a substrate.

The absorbing means of each stage may be comprised of a carbon-based semiconductor material which, in one aspect of the present invention, is a carboloid and more specifically C₆₀ carboloid being doped with at least one base element or compound that is selected based upon the wavelength range of light to be absorbed. Each element or compound is selected for efficient photon absorption and subsequent electron excitation. The elements or compounds define a particular band gap, which determines the required threshold velocity of incident photons for releasing electrons from receptors.

In one aspect of the present invention, each junction is defined in a different stage possessing a different band gap. The different band gaps are disposed among the stages in such a way that the highest energy (and highest frequency) incident photons are absorbed near the exposed surface of the PV cell and the consecutively lower energy (and lower frequency) incident photons penetrate higher stages to be absorbed at consecutively lower stages. With the exception of the bottom stage, which can be opaque, each stage may be effectively transparent to all incident light wavelengths except for those within its particular photon absorption range. Thus each stage may be composed such that it optimally absorbs a particular wavelength range of photons, and the plurality of stages together are operable to absorb a wide range of overall wavelengths of photons. In one aspect of the present invention, six stages may be used. It has been found that in such an implementation.

Optionally, the stages may be composed so as to partially overlap in wavelength absorption with adjacent stages. This could be applied within sub-layers. It should be understood that there may be multiple layers within the arrangement for addressing the same spectrum, resulting in sub-layering for achieving better absorption. For example, additional residue can be absorbed by other elements from adjacent stages mixed into the absorbing means of a particular stage in relatively smaller amounts. This arrangement provides absorption outside the preferred frequency for the particular layer. In one aspect of the present invention, the absorbing means in each stage are composed predominantly of an element that absorbs primarily photons within the particular absorption range of that particular stage, but mixed with smaller proportions of at least some of the elements used in the other stages so that “spillover” from photons which are within the absorption range of adjacent stages but are not absorbed (due for example to saturation of the absorbing means in that stage) may be absorbed by a successive stage.

The absorbing means of each stage, as previously mentioned, may be composed of a carbide-based semiconductor and at least one base element or compound, but with proportionally greater amounts of the particular element for absorbing the wavelength range of photons desired for that stage. In one aspect of the present invention, the base elements and spectral absorption characteristics are:

| | |
|---|---|
| Iridium: | Short wavelength UVA, UVB; |
| Iridium/Titanium: | Higher excitation UVA, UVB; |
| Gallium: | Visible Blue and Long Wavelength UV cascade; |
| Cadmium: | Visible Yellow/Green; |
| Beryllium: | Short Wavelength IR; |
| Beryllium/Indium: | Long Wavelength and Higher excitation IR. |

In addition to those base elements described above, a person skilled in the art would recognize that various other elements could be used based on the wavelength of light to be absorbed.

Accordingly, the first stage may comprise a series of layer sequences, each layer sequence comprising two cathode layers and an anode layer, the anode layer comprising a waveguide and the cathode layers comprising absorbing means, which absorb high energy photons within the short wavelength ultraviolet (UV) portion of the emr spectrum.

The waveguide may be linked to a terminal projecting through the encapsulate and thus exposed from the photovoltaic cell for connection to a conductive grid linked to the photovoltaic panel output (not shown). The absorbing means may be provided with a back contact, which can also serve as an energy sink (including a heat sink). The back contact may be conductively linked to a terminal projecting through the encapsulate and thus exposed from the photovoltaic cell for linking to a negative bus leading to the photovoltaic panel output (not shown).

The second stage may comprise a similar series of layer sequences, wherein the absorbing means comprises primarily gallium for absorbing photons within the visible blue and long wavelength UV portions of the spectrum. The second stage may share the other characteristics, including the conductive grid link and the negative bus link as described in accordance with the first stage.

Similarly, the third, fourth, fifth and sixth stages may comprise a similar series of layer sequences, wherein the absorbing means of each stage comprises primarily the materials referred to above for absorbing photons within the spectral ranges referred to above. These stages also may share the other characteristics including the conductive grid link and the back contact link as described in accordance with the first stage

### Heat Sink

Typically photovoltaic panels generate heat during operation. The heat is caused by unabsorbed photons (i.e. photon absorption inefficiency). Furthermore, as the panel heats its efficiency lowers, causing a further heat increase. The PV cell of the present invention minimizes heat generation due to its relatively high efficiency. In one aspect of the present invention, the PV cell comprises further heat dissipation means for further optimizing photon absorption efficiency.

The heat dissipation means may comprise either or both of the conductive grid and the substrate.

The conductive grid, as previously mentioned, preferably has a high thermal conductivity. Thus when disposed in proximity with the waveguide, the conductive grid pulls heat away from the anode layers and dissipates the heat to its surroundings, which may be outside the encapsulate. The back contact, also preferably having a high thermal conductivity, provides the same benefit for the cathode layers.

The substrate may also be constructed to maximize heat dissipation. Also provided in one aspect of the present invention is a base plate of the substrate preferably of metal (such as titanium, which has a high thermal conductivity). The base plate may be structured into an irregular concave parabolic shape to displace heat more effectively than a planar plate. The irregularities may also comprise layering to dissipate heat more quickly. The heated base plate is linked to the load, since the substrate comprises the terminals of the PV cell. Thus any remaining heat is diverted to the load and not retained within the PV cell.

It should be understood that the combination of elements referenced herein, and specifically the use of carbon and silicon in combination has implications on both heat sink and photon excitation. Specifically, the carbon provides heat absorption for the silicate within the layers (or sub-layers), and this in turn provides greater photon excitation within the layer (or sub-layer).

### Example in Operation

The present invention is operable to generate electricity using energy from incident photons. The following describes the PV cell of the present invention, in one particular aspect thereof, comprising each aspect described more fully above.

In operation, sunlight strikes the top layer of the upper stage of the PV cell. The top layer comprises a first absorbing means and is the cathode. The photons of the sunlight are accelerated by an influence exerted from the waveguide of the upper stage in the middle layer or anode. The receptors within the absorbing means in the top layer preferentially capture the highest energy photons and correspondingly release electrons. The remaining highest energy photons may penetrate through the top layer of the upper stage to the bottom layer of the upper stage, which comprises another cathode having a second absorbing means for the same energy range. These photons are further accelerated towards receptor of the bottom layer. Preferentially these remaining photons are captured in the second absorbing means and electrons are corresponding released.

The layer in between the two absorbing means is the waveguide. The waveguide exerts an influence on the photons and also on the released electrons. The influence on the electrons directs the electrons towards the waveguide. The waveguide, which may comprise a plurality of interleaved coil elements, may have at least one element substantially in-phase with the electron operable to capture the electron.

An electrical potential is created between the terminals of the cathode layers and anode layer, respectively, and thus through conductors leading to the substrate portions. The conductors are the conductive grid and the back contact. This potential will cause electrons to flow through an external conductive path created between the substrate portions to a load as the electrons try to replenish the electron-depleted cathode layer.

The upper stage is formed primarily from iridium and iridium/titanium, which preferentially absorbs photons within the UV portion of the spectrum. As the unabsorbed spectral components of the sunlight progress downwardly through the first stage, and the compositions of the cathode and anode semiconductor layers changes such that the proportions of primary elements used in the lower stages increase and the proportion of iridium decreases in each sequence of layers, greater photonic absorption of lower energy photons starts to occur. Most of the longer wavelength photons in the remaining portion of the sunlight spectrum penetrate through the first stage and into the photovoltaic cell. Unabsorbed photons in the short wavelength UV portion of the spectrum may continue deeper into the cell to lower stages.

The majority of photons in the short wavelength UV portion of the spectrum having been filtered out by the first stage, the remaining spectral components of the sunlight penetrate through to the second stage. The second stage is composed primarily of gallium, which preferentially absorbs photons within the visible blue and long wavelength UV portions of the spectrum. Through the mechanism described above, the absorbed photons create an electrical potential between the terminals of the cathode layers and anode layer respectively, and thus through conductors leading to the substrate portions. Some of the longer wavelength photons in the remaining portion of the sunlight spectrum are absorbed by the second stage, particularly as the depth increases and the proportion of gallium in relation to the primary semiconductor components used in the other stages decreases, but most of the longer wavelength photons in the remaining portion of the sunlight spectrum penetrate through the second stage.

The remaining spectral components of the sunlight penetrate through to the next lower stage. The third stage is composed primarily of cadmium-beryllium which preferentially absorbs photons within the green through short wavelength infrared portions of the spectrum. Through the mechanism described above, the absorbed photons create an electrical potential between the terminals of the cathode layers and anode layer and thus through the conductors leading to the substrate portions. As in the second stage, some of the longer wavelength photons in the remaining portion of the sunlight spectrum are absorbed by the third stage, particularly as the depth increases and the proportion of cadmium-beryllium in relation to the primary semiconductor components used in the other stages decreases, but most of the longer wavelength photons in the remaining portion of the sunlight spectrum penetrate through the third stage to the fourth stage.

The majority of photons having wavelengths shorter than the short wavelength IR portion of the spectrum having been filtered out by the first three stages, the residual spectral components of the sunlight penetrate through to the fourth stage. The fourth stage is composed of beryllium or beryllium/indium, which preferentially absorbs photons within the long wavelength UV portion of the spectrum. Through the mechanism described above, the absorbed photons create an electrical potential between the terminals of the cathode layers and anode layer, and thus through the conductors leading to the substrate portions.

Staging the absorption of photons using different types of semiconductors in this fashion increases photon absorption, by effectively reducing the likelihood of photonic saturation at each stage (and at each sequence of layers within each stage). Whereas a conventional silicon-based photovoltaic cell which absorbs the full spectrum of sunlight in a single stage can quickly become saturated in bright sunlight, resulting in a high proportion of unabsorbed photons, the present invention effectively frequency-divides the sunlight spectrum into components, which reduces the likelihood of reaching the saturation point in any particular stage and results in a significantly lower proportion of unabsorbed photons.

Further, this arrangement extends the life of the photovoltaic cell because the most energetic photons, in the short wavelength UV portion of the spectrum, tend to degrade conventional silicon-based photovoltaic cells relatively quickly. In the preferred embodiment of the invention, the most energetic photons are largely filtered from the sunlight spectrum before the light penetrates into the photovoltaic cell.

The substrate portions feeding a current to the back contact and drawing a current from the conductive grid, are respectively coupled to the positive and negative electrical buses leading to the output of the photovoltaic panel. The current from the plurality of photovoltaic cells in the photovoltaic panel is cumulative, and thus the power output of the photovoltaic panel comprises is determined by the number of photovoltaic cells in the panel.

Heat may be removed from the cell via the heat sink function of the back contacts and substrate portions, increasing the efficiency of the cell.

It should be understood that the structures and arrangements described herein may be created using advanced IC manufacturing methods.

Various embodiments of the present invention having been thus described in detail by way of example, it will be apparent to those skilled in the art that variations and modifications may be made without departing from the invention.

### Other Applications

The waveguide, in another aspect of the present invention, can be applied to areas outside of PV cells. For example, any application requiring the use of energy travelling between two known points and requiring minimal energy loss can be optimized by use of the waveguide.

In the field of communications for example, the waveguide of the present invention can be used to enable duplex communication. Waveguides may be provided at each end of a communication link. Each end may also transmit data out of phase from the other link, causing minimal interference within the link. However due to the phase insensitivity of the waveguide, it may receive the data regardless of its phase.

In another example, the waveguide can provide a narrow laser band. Due to the waveguide oscillation, a tighter focal point of the laser may be obtained, providing a more precise laser.

In yet another example, the waveguide may be used in ground penetrating radar. For example, a laser drill may be used for core samples deep below the ground. Typical laser drills encounter such problems as drilling to a point occupied by silicon, which creates a refracted mirror potentially causing a melt down. The waveguide of the present invention can be used to target particular frequencies known to avoid these problems.

The O-ring circuit application can also be used with other methods of solar cell manufacture such as mono-crystalline and poly-crystalline. As well, the concave lattice network formed through the laser etching process can also be applied to traditional silicates to produce better overall efficiency with oblique light angles.

We claim:

1. A photovoltaic cell characterized by at least one energy guiding means, the energy guiding means including at least one electron donor and at least one electron acceptor, wherein the at least one electron donor is operable to release electrons based on absorption of photons and the at least one electron acceptor is operable to accelerate photons towards the at least one electron donor and attract electrons released by the at least one electron donor, wherein the at least one electron donor and the at least one electron acceptor are adapted to be linked to a load therebetween.

2. The photovoltaic cell of claim 1, characterized in that the at least one electron acceptor comprises at least one waveguide, the at least one waveguide constructed so as to be substantially phase insensitive to the different phases of the attracted electrons.

3. The photovoltaic cell of claim 2, characterized in that the at least one waveguide is formed from at least one interleaved coil element.

4. The photovoltaic cell of claim 3, characterized in that a plurality of interleaved coil elements are provided, each element being in close proximity to an adjacent element but not in contact with an adjacent element.

5. The photovoltaic cell of claim 1, characterized in that a plurality of energy guiding means are provided, each energy guiding means operable to convert different wavelength ranges of incident light to electric charges.

6. The photovoltaic cell of claim 9, characterized in that the energy guiding means are disposed in consecutively ordered stages such that the energy guiding means operable to convert relatively higher wavelength ranges are disposed nearer the light-exposed surface and the energy guiding means operable to convert the relatively lower wavelength ranges are disposed nearer the substrate.

7. A photovoltaic cell characterized by at least one energy guiding means, the energy guiding means including at least one electron donor and at least one electron acceptor, wherein the at least one electron donor includes at least one photon receptor adapted to have a surface disposed at an angle normal to a range of incident photon angles, the at least one photon receptor releasing electrons based on photons striking the surface, and the at least one electron acceptor is operable to attract electrons released by the at least one electron donor, wherein the at least one electron donor and the at least one electron acceptor are adapted to be linked to a load therebetween.

8. The photovoltaic cell of claim 7, characterized in that the at least one photon receptor is constructed within or across a lattice of nanostructures.

9. The photovoltaic cell of claim 8, characterized in that the lattice of nanostructures comprises at least one nanotube.

10. The photovoltaic cell of claim 9, characterized in that a plurality of nanotubes is provided, wherein the nanotubes are formed from a carbon or silicon carbon lattice, and wherein at least two of the nanotubes are bonded together using hydrazine as a bonding agent at the carbon level.

11. The photovoltaic cell of claim 8, characterized in that the at least one photon receptor is formed in a crystalline arrangement in or across the lattice of nanostructures, wherein the crystalline arrangement is not bonded to the lattice.

12. The photovoltaic cell of claim 7, characterized in that each receptor is a three dimensionally parabolic shape for optimizing the capture of incident light at varying angles.

13. The photovoltaic cell of claim 7, characterized in that the receptors are disposed within the at least one electron donor along a plurality of levels.

14. The photovoltaic cell of claim 1 or claim 7, characterized in that the first electrically conductive terminal is a first portion of a substrate and the second electrically conductive terminal is a second portion of the substrate, the substrate having a parabolic shape operable to dissipate heat.

15. The photovoltaic cell of claim 1 or claim 7, characterized in that a plurality of energy guiding means are provided, each energy guiding means operable to convert different wavelength ranges of incident light to electric charges.

16. The photovoltaic cell of claim 15, characterized in that the plurality of energy guiding means are disposed in consecutively ordered stages such that the energy guiding means operable to convert relatively higher wavelength ranges are disposed nearer the light-exposed surface and the energy guiding means operable to convert the relatively lower wavelength ranges are disposed nearer the substrate.
